(19) United States
(12) Patent Application Publication
(10) Pub. No.: US 2026/0020361 A1
(43) Pub. Date: Jan. 15, 2026

(54) IMAGE SENSOR AND METHOD OF MANUFACTURING THE SAME

(71) Applicant: Samsung Electronics Co., Ltd., Suwon-si (KR)

(72) Inventors: Daehoon KIM, Suwon-si (KR); Keunhyoung PARK, Suwon-si (KR); Dongjun OH, Suwon-si (KR); Seungjae OH, Suwon-si (KR)

(73) Assignee: Samsung Electronics Co., Ltd., Suwon-si (KR)

(21) Appl. No.: 19/264,013

(22) Filed: Jul. 9, 2025

(30) Foreign Application Priority Data
Jul. 11, 2024 (KR) 10-2024-0091936

(51) Int. Cl. H10F 39/00; H10F 39/18

(52) U.S. Cl. CPC H10F 39/80373; H10F 39/014; H10F 39/182; H10F 39/807; H10F 39/809

(57) ABSTRACT

An image sensor includes a deep device isolation pattern in a substrate and defining photodiode regions, a shallow device isolation pattern (STI) filling a first shallow trench, recessed from a surface of the substrate, to an active region in each of the photodiode regions, a second shallow trench in the STI on opposite sides of the active region and exposing portions of opposite side surfaces of the active region, a gate structure on an upper surface of the active region and on the opposite side surfaces exposed by the second shallow trench, a floating diffusion region in the active region, and a gate spacer on side surfaces of the transfer gate. A portion of the gate spacer may be in the second shallow trench, and a lower end of the portion of the gate spacer may be between the first and second surfaces of the substrate.

### CROSS-REFERENCE TO RELATED APPLICATION(S)

This U.S. non-provisional application claims priority under 35 USC § 119 to Korean Patent Application No. 10-2024-0091936, filed on Jul. 11, 2024, in the Korean Intellectual Property Office, the disclosure of which is herein incorporated by reference in its entirety.

### BACKGROUND

The present disclosure relates to an image sensor and a method of manufacturing the same.

An image sensor is a semiconductor device that is configured to convert an optical image into an electrical signal. In recent years, with the development of the computer and communication industries, the demand for image sensors with improved performance and/or reliability has been increasing across various fields, including digital cameras, camcorders, personal communication systems (PCS), gaming devices, security cameras, medical micro-cameras, etc. The classification for image sensors may include charge-coupled device (CCD) type image sensors and complementary metal-oxide-semiconductor (CMOS) type image sensors. A CMOS-type image sensor may include a plurality of pixels, e.g., arranged in a two-dimensional array. Each of the plurality of pixels may include a photodiode PD. The photodiode PD may be configured to convert incident light into an electrical signal.

### SUMMARY

One or more example embodiments provide an image sensor configured to reduce or prevent an electrical short-circuit between transfer gates and a method of manufacturing the image sensor.

According to one or more example embodiments, an image sensor includes a substrate having a first surface and a second surface, the second surface opposing the first surface, a deep device isolation pattern in the substrate and defining photodiode regions, a shallow device isolation pattern filling a first shallow trench, the first shallow trench recessed from the first surface, the shallow device isolation pattern defining an active region in each of the photodiode regions, a second shallow trench in the shallow device isolation pattern on opposite sides of a portion of the active region such that the second shallow trench exposes opposite side surfaces of the portion of the active region, a transfer gate on an upper surface of the portion of the active region and on the opposite side surfaces exposed by the second shallow trench, a gate insulating layer between the transfer gate and the active region, a floating diffusion region in the active region and under one side of the transfer gate, and a gate spacer on side surfaces of the transfer gate. A portion of the gate spacer may be in the second shallow trench, and a lower end of the portion of the gate spacer may be at a level between the first and second surfaces of the substrate.

According to one or more example embodiments, an image sensor includes a substrate having a first surface and a second surface, the second surface opposite to the first surface, a deep device isolation pattern in the substrate and defining photodiode regions, a shallow device isolation pattern filling a first shallow trench, the first shallow trench recessed from the first surface, a shallow device isolation pattern defining an active region in each of the photodiode regions, a second shallow trench in the shallow device isolation pattern on opposite sides of a portion of the active region and exposing opposite side surfaces of the portion of the active region, a transfer gate on an upper surface of the portion of the active region and on the opposite side surfaces exposed by the second shallow trench, a gate insulating layer between the transfer gate and the active region, a floating diffusion region in the active region on one side of the transfer gate, a gate spacer on side surfaces of the transfer gate, and an interlayer dielectric disposed on the first surface of the substrate to cover the transfer gate and the gate spacer. The second shallow trench may extend laterally, in a plan view, such that the second shallow trench crosses the deep device isolation pattern, and such that a bottom surface of the second shallow trench may expose the deep device isolation pattern. A portion of the gate spacer may be in the second shallow trench, and a lower end of the portion of the gate spacer may be between the first surface and the second surface of the substrate. The interlayer dielectric may fill a remaining portion of the second shallow trench.

According to one or more example embodiments, a method of manufacturing an image sensor includes forming a first shallow trench in a substrate such that the first shallow trench defines an active region, forming a shallow device isolation pattern by filling the first shallow trench, forming a photoelectric conversion region in the substrate, forming a second shallow trench by etching a portion of the shallow device isolation pattern, the second shallow trench exposing opposite side surfaces of a portion of the active region, forming a gate insulating layer after the forming the second shallow trench, forming a transfer gate on the gate insulating layer such that the transfer gate covers an upper surface of the portion of the active region and the opposite side surfaces exposed by the second shallow trench, and forming a gate spacer on side surfaces of the transfer gate. A portion of the gate spacer may be formed in the second shallow trench.

### BRIEF DESCRIPTION OF DRAWINGS

FIG. 1 is a block diagram of an image sensor according to one or more example embodiments.

FIG. 2 is a circuit diagram of pixels included in a pixel array of an image sensor according to one or more example embodiments.

FIGS. 3A and 3B are circuit diagrams of pixels in image sensors according to one or more example embodiments.

FIG. 4 is a cross-sectional view of an image sensor according to one or more example embodiments.

FIG. 5 is a plan view of a portion of an image sensor according to one or more example embodiments.

FIG. 6 is a cross-sectional view taken along line I-I′ of FIG. 5.

FIG. 7 is a cross-sectional view taken along line II-II′ of FIG. 5.

FIG. 8 is a cross-sectional view taken along line III-III′ of FIG. 5.

FIG. 9 is a cross-sectional view corresponding to line I-I′ of FIG. 5, illustrating an image sensor according to one or more example embodiments.

FIG. 10 is a plan view of a portion of an image sensor according to one or more example embodiments.

FIG. 11 is a cross-sectional view taken along line II-II′ of FIG. 10.

FIGS. 12 to 17 are plan views of portions of image sensors according to one or more example embodiments.

FIGS. 18 and 19 are plan views of portions of image sensors according to one or more example embodiments.

FIG. 20 is a cross-sectional view of an image sensor according to one or more example embodiments.

FIGS. 21 to 28 are cross-sectional views illustrating a method of manufacturing a portion of an image sensor according to one or more example embodiments.

FIG. 29 is a cross-sectional view of an image sensor according to one or more example embodiments.

### DETAILED DESCRIPTION

Hereinafter, one or more example embodiments will be described with reference to the accompanying drawings, wherein like reference numerals refer to like elements throughout.

Spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Unless expressly indicated otherwise, elements within a functional unit may communicate with each other, through a bus such as, but not limited to, a wireless bus and/or a wired bus, to exchange information, stored in various formats such as, but not limited to, an analog format and/or a digital format, and may communicate to transmit and/or receive the information in various manners, such as but not limited to a one-way manner, a two-way manner, or a multiway manner; the information may be sent and/or received in various manners such as, but not limited to, a serial manner and/or a parallel manner. However, the example embodiments are not limited thereto.

Additionally, functional elements, unless expressly indicated otherwise, may include (or be) processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

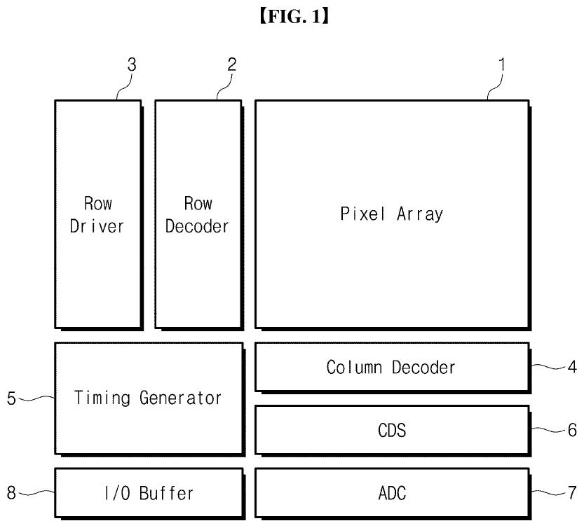

FIG. 1 is a block diagram of an image sensor according to one or more example embodiments.

Referring to FIG. 1, an image sensor according to one or more example embodiments may include a pixel array 1, a row decoder 2, a row driver 3, a column decoder 4, a timing generator 5, a correlated double sampler (CDS) 6, an analog-to-digital converter (ADC) 7, and an input/output buffer (I/O buffer) 8. For clarity of illustration, connections between the pixel array 1, the row decoder 2, the row driver 3, the column decoder 4, the timing generator 5, the correlated double sampler (CDS) 6, the analog-to-digital converter (ADC) 7, and the input/output buffer (I/O buffer) 8 are not illustrated; however, the image sensor may include connections between the pixel array 1, the row decoder 2, the row driver 3, the column decoder 4, the timing generator 5, the correlated double sampler (CDS) 6, the analog-to-digital converter (ADC) 7, and the input/output buffer (I/O buffer) 8 configured to facilitate communication therebetween. In at least some example embodiments, the connections may be or include conductive structures such as conductive pads, wires, and/or the like.

The pixel array 1 may include a plurality of pixels arranged two-dimensionally (or in a matrix), and the pixels may be configured to convert optical signals into electrical signals. The pixel array 1 may be driven by a plurality of driving signals (for example, a pixel select signal, a reset signal, and/or a charge transfer signal) transmitted from the row driver 3. The converted electrical signals may be provided to the correlated double sampler 6. The plurality of driving signals may be received from and/or generated based on instructions executed by a host including processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The row driver 3 may be configured to provide the pixel array 1 with a plurality of driving signals to drive a plurality of pixels based on a decoding result from the row decoder 2. When the pixels are arranged in a matrix, the driving signals may be provided in units of rows.

The timing generator 5 may be configured to provide a timing signal and a control signal to the row decoder 2 and the column decoder 4.

The correlated double sampler 6 may be configured to receive electrical signals generated by the pixel array 1, and to hold and sample the received electrical signals. The correlated double sampler 6 may perform double sampling on a specific noise level and a signal level corresponding to the electrical signal to output a difference level corresponding to a difference between the noise level and the signal level.

The analog-to-digital converter 7 may be configured to convert an analog signal, corresponding to the difference level output from the correlated double sampler 6, into a digital signal and output the digital signal.

The input/output buffer 8 may be configured to latch digital signals and sequentially output the latched signals to an image signal processor, not illustrated, based on the decoding result from the column decoder 4.

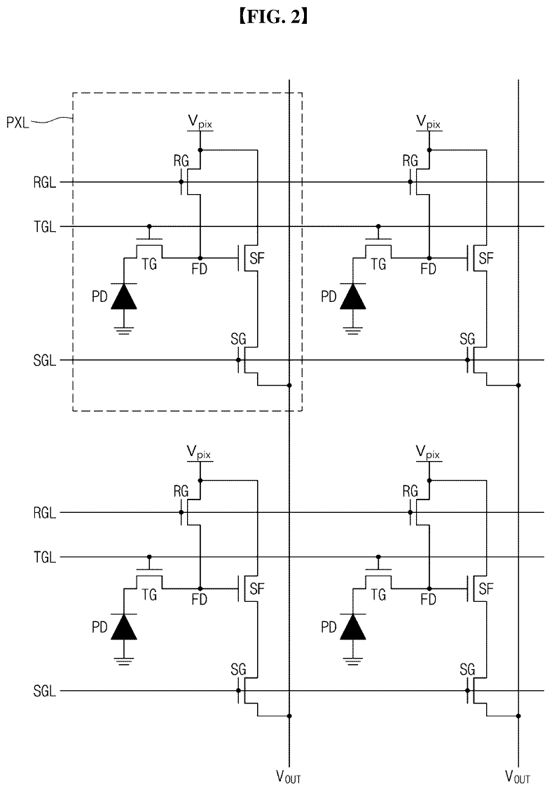

FIG. 2 is a circuit diagram of pixels included in a pixel array of an image sensor according to one or more example embodiments.

Referring to FIG. 2, the pixel array may include a plurality of pixels PXL arranged in a matrix. Each of the pixels PXL may include a transfer transistor TG and logic transistors RG, SG, and SF. The logic transistors RG, SG, and SF may include a reset transistor RG, a select transistor SG, and a source follower transistor SF. Each of the pixels PXL may also include a photodiode PD and a floating diffusion region FD.

The photodiode PD may be configured to generate and accumulate photocharges in proportion to the amount (e.g., duration and/or intensity) of externally incident light. The photodiode PD may include a photoelectric conversion element (or photoelectric conversion region), a phototransistor, a photogate, a pinned photodiode, or combinations thereof. The transfer transistor TG may transfer the photocharges, generated by the photodiode PD, to the floating diffusion region FD. The transfer gate of the transfer transistor TG may be connected to a transfer gate line TGL. The floating diffusion region FD may cumulatively store the photocharges transferred from the photodiode PD.

A gate of the source follower transistor SF may be connected to the floating diffusion region FD. A drain terminal of the source follower transistor SF may receive a supply voltage through a connection to a power supply voltage Vₚᵢₓ. The source follower transistor SF may be controlled based on the amount of photocharges accumulated in the floating diffusion region FD.

The reset transistor RG may periodically reset charges accumulated in the floating diffusion region FD. A gate of the reset transistor RG may be connected to a reset gate line RGL. A source terminal of the reset transistor RG may be connected to the floating diffusion region FD, and a drain terminal of the reset transistor RG may be connected to the power supply voltage Vₚᵢₓ. When the reset transistor RG is turned on, the power supply voltage at the power supply voltage Vₚᵢₓ may be applied to the floating diffusion region FD through the reset transistor RG. For example, when the reset transistor RG is turned on, charges accumulated in the floating diffusion region FD may be discharged by the power supply voltage to reset the floating diffusion region FD.

The source follower transistor SF may serve as a source follower buffer amplifier. The source follower transistor SF may amplify a potential change in the floating diffusion region FD and output the amplified potential change to an output line VOUT.

A gate of the select transistor SG may be connected to a select gate line SGL. A drain terminal of the select transistor SG may be connected to the source terminal of the source follower transistor SF, and a source terminal of the select transistor SG may be connected to an output line V_{OUT}. Select transistors SG of pixels PXL to be read in units of rows may be selected by a select signal applied through a corresponding select gate line SGL. When the select transistor SG is turned on, the potential changes amplified by the source follower transistor SF may be output to the output line V_{OUT} through the select transistor SG.

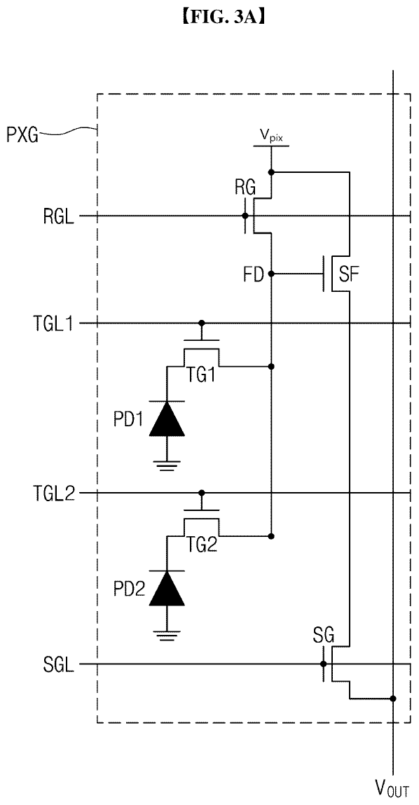

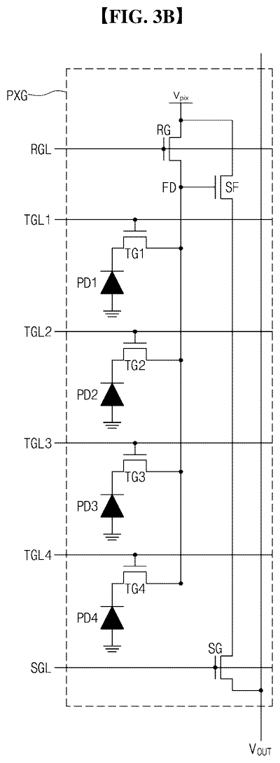

Each of the pixels PXL in FIG. 2 are illustrated as including a single photodiode PD, a transfer transistor TG, and logic transistors RG, SG, and SF, but embodiments are not limited thereto. In some example embodiments, adjacent pixels may form a pixel group PXG, and the pixels in the pixel group may share at least one of the logic transistors RG, SG, and SF. Examples related thereto will be described with reference to FIGS. 3A and 3B.

FIGS. 3A and 3B are circuit diagrams of pixels in image sensors according to one or more example embodiments.

Referring to FIGS. 3A and 3B, a pixel array may include a plurality of pixel groups PXG, and each of the pixel groups PXG may include a plurality of pixels. A circuit diagram of a single pixel group PXG is illustrated in each of FIGS. 3A and 3B.

Referring to FIG. 3A, in some example embodiments, a pixel group PXG may include two pixels (for example, first and second pixels). The first pixel may include a first transfer transistor TG1 and a first photodiode PD1, and the second pixel may include a second transfer transistor TG2 and a second photodiode PD2. A gate of the first transfer transistor TG1 may be connected to a first transfer gate line TGL1, and a gate of the second transfer transistor TG2 may be connected to a second transfer gate line TGL2. The first and second pixels may share the reset transistor RG, source follower transistor SF, and select transistor SG described above.

Referring to FIG. 3B, in some example embodiments, a pixel group PXG may include four pixels (for example, first to fourth pixels). The first to fourth pixels may include first to fourth transfer transistors TG1, TG2, TG3, and TG4 and first to fourth photodiodes PD1, PD2, PD3, and PD4, respectively. Gates of the first to fourth transfer transistors TG1, TG2, TG3, and TG4 may be connected to first to fourth transfer gate lines TGL1, TGL2, TGL3, and TGL4, respectively. The first to fourth pixels may share the reset transistor RG, the source follower transistor SF, and the select transistor SG described above.

In the example embodiments of FIGS. 3A and 3B, the pixel group PXG may include two or four pixels. However, embodiments are not limited thereto. The number of pixels in a pixel group PXG may vary. For example, a pixel group PXG may include eight pixels.

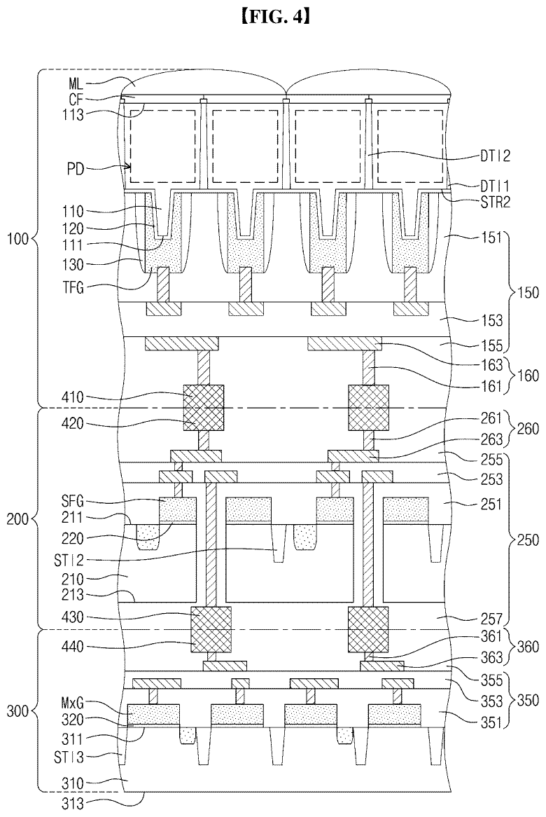

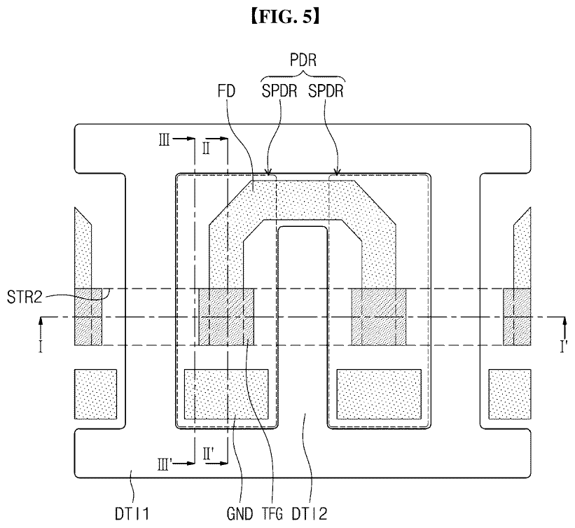

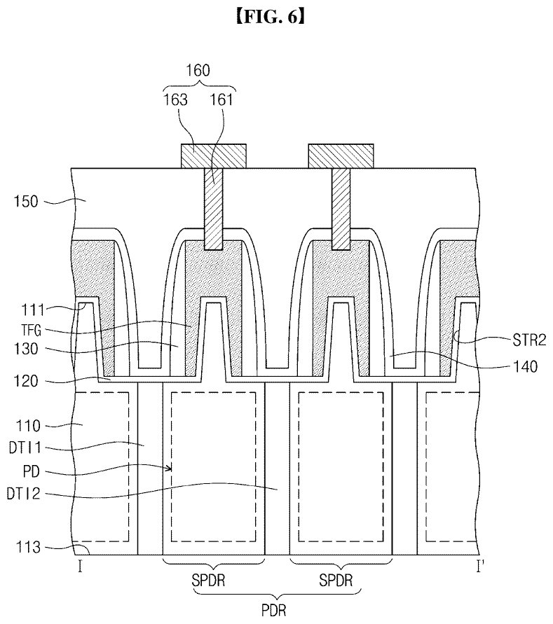

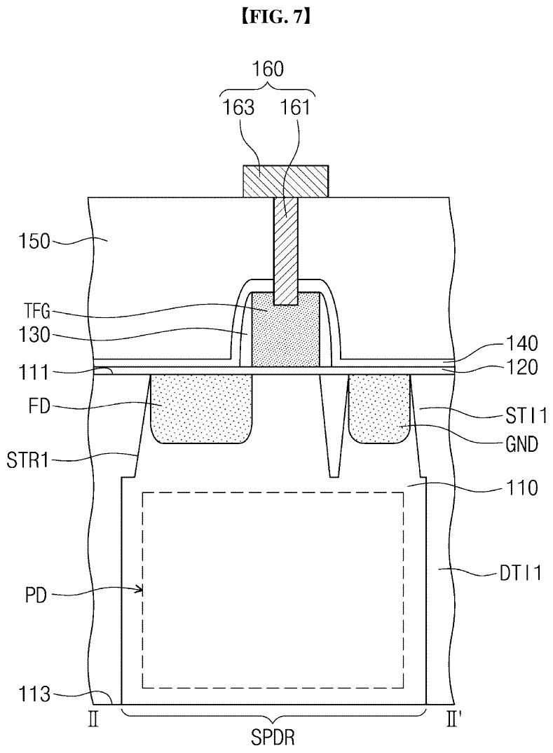

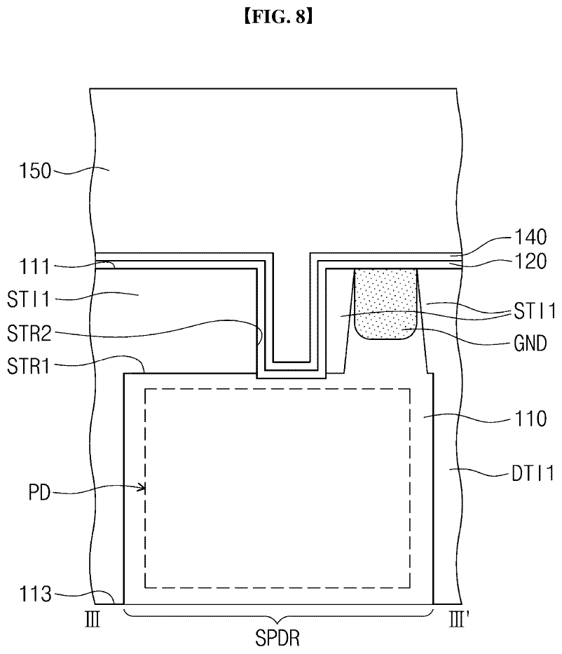

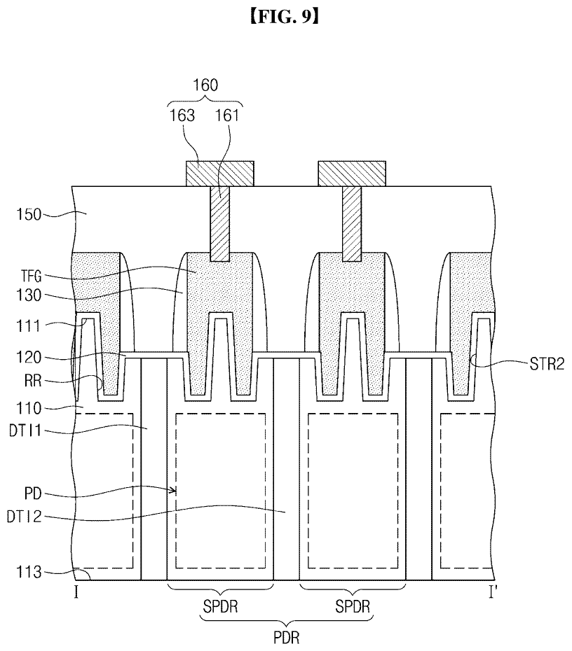

FIG. 4 is a cross-sectional view of an image sensor according to one or more example embodiments. FIG. 5 is a plan view of a portion of an image sensor according to one or more example embodiments. FIG. 6 is a cross-sectional view taken along line I-I′ of FIG. 5, FIG. 7 is a cross-sectional view taken along line II-II′ of FIG. 5, and FIG. 8 is a cross-sectional view taken along line III-III′ of FIG. 5. FIG. 9 is a cross-sectional view corresponding to line I-I′ of FIG. 5, illustrating an image sensor according to one or more example embodiments.

Referring to FIG. 4, an image sensor according to one or more example embodiments may include first to third structures 100, 200, and 300. The first structure 100 may be stacked on the second structure 200, and the second structure 200 may be stacked on the third structure 300. Thus, the image sensor may have a stacked structure. The first structure 100 may be referred to as a first chip, a photoelectric conversion chip, or a photoelectric conversion structure. The second structure 200 may be referred to as a second chip, an intermediate chip, or an intermediate structure. The third structure 300 may be referred to as a third chip, a peripheral circuit chip, or a peripheral circuit structure. The first structure 100 and the second structure 200, and the second structure 200 and the third structure 300, may be bonded by one or more bonding methods and electrically connected by one or more connection methods. For example, in at least some example embodiments, the first structure 100 and the second structure 200, and the second structure 200 and the third structure 300, may be bonded by a hybrid bonding such as Cu—Cu bonding and/or the like.

Referring to FIG. 4 and FIGS. 5 to 8, the first structure 100 may include a first substrate 110, a Photodiode PD, a first deep device isolation pattern DTI1, a second deep device isolation pattern DTI2, a first shallow trench STR1, a first shallow device isolation pattern STI1, a second shallow trench STR2, a floating diffusion region FD, a ground region GND, a first gate insulating layer 120, a transfer gate TFG, a gate spacer 130, a first interlayer dielectric 150, a first contact complex 160, a first bonding pad 410, a color filter CF, and a microlens ML. The first substrate 110 may be referred to as a photoelectric conversion substrate.

The first substrate 110 may have a first surface 111 and a second surface 113 opposing the first surface 111. The first surface 111 may correspond to a front surface of the first substrate 110, and the second surface 113 may correspond to a rear surface of the first substrate 110. The substrate 110 may be configured such that light may be incident on to the second surface 113 of the first substrate 110. For example, the second surface 113 of the first substrate 110 may be a light-incident surface.

The first surface 111 of the first substrate 110 may face the second structure 200 of FIG. 4, and FIG. 5 is a plan view illustrating the first surface 111 of the first substrate 110. Therefore, FIGS. 5 to 8 illustrate a flipped shape of the first substrate 110 and transfer gate TFG of FIG. 4.

The first substrate 110 may be and/or include a semiconductor substrate, such as a silicon (Si) substrate, a germanium (Ge) substrate, a silicon-germanium (Si—Ge) substrate, a group II-VI compound semiconductor substrate, a group III-V compound semiconductor substrate, a silicon-on-insulator (SOI) substrate, a combination thereof, and/or the like. The first substrate 110 may include impurities of a first conductivity type, thereby having the first conductivity type. For example, the impurities of the first conductivity type may be group III elements. For example, the impurities of the first conductivity type may include P-type impurities such as at least one of aluminum (Al), boron (B), indium (In), and/or gallium (Ga).

The Photodiode PD may be disposed within the first substrate 110. The Photodiode PD may include impurities of a second conductivity type different from the first conductivity type, thereby having the second conductivity type. For example, the impurities of the second conductivity type may be group V elements. For example, the impurities of the second conductivity type may include N-type impurities such as at least one of phosphorus (P), arsenic (As), bismuth (Bi), and/or antimony (Sb).

The Photodiode PD and a remainder of the first substrate 110 may form a PN junction therebetween to constitute the above-described photodiode PD.

In some example embodiments, the first deep device isolation pattern DTI1 may be disposed in the first substrate 110 to define photodiode regions PDR within the first substrate 110, and at least one Photodiode PD may be disposed in each of the photodiode regions PDR.

The first deep device isolation pattern DTI1 may penetrate through the first substrate 110. For example, the first deep device isolation pattern DTI1 may penetrate through the first and second surfaces 111 and 113 of the first substrate 110 and a substrate body between the first and second surfaces 111 and 113.

In a plan view, the first deep device isolation pattern DTI1 may be formed in the first substrate 110 to surround each of the photodiode regions PDR. For example, the first deep device isolation pattern DTI1 may be formed by a technique in which a deep trench formed by patterning the first substrate 110 is filled with an insulating material, for example, a deep trench isolation (DTI) technique. In some example embodiments, a photodiode region PDR may be a portion of the first substrate 110 surrounded by the first deep device isolation pattern DTI1.

In some example embodiments, the first deep device isolation pattern DTI1 may include a conductive isolation layer disposed in a deep trench and an insulating liner between the first substrate 110 and the conductive isolation layer. The conductive isolation layer may include a conductive material such as a doped semiconductor material (for example, doped polysilicon). The conductive isolation layer may be spaced apart from the first substrate 110 by an insulating liner. The insulating liner may include an insulating material. Thus, the conductive isolation layer may be electrically isolated from and the first substrate 110 during the operation of an image sensor.

In some example embodiments, each of the photodiode regions PDR may include at least two sub-photodiode regions SPDR. The Photodiodes PD may be disposed in each of the sub-photodiode regions SPDR. For example, at least two Photodiodes PD may be disposed in each photodiode region PDR. When each photodiode region PDR includes at least two sub-photodiode regions SPDR, the photodiode region PDR may correspond to the pixel group PXG in FIG. 3A or 3B. For example, the pixel group PXG of FIG. 3A or 3B may be formed on and in each photodiode region PDR, and each pixel of FIG. 3A or 3B may be formed on and in each of the sub-photodiode regions SPDR.

The at least two sub-photodiode regions SPDR may be isolated from each other by at least one isolation techniques among various isolation techniques. For example, the sub-photodiode regions SPDR may be isolated from each other by a doping isolation technique. For example, a doped isolation region may be provided between at least two sub-photodiode regions SPDR. Alternatively, the sub-photodiode regions SPDR may be isolated from each other by a doped isolation region and at least one deep device isolation pattern. For example, a doped isolation region and at least one deep device isolation pattern may be provided between at least two sub-photodiode regions SPDR. Alternatively, only at least one deep device isolation pattern may be provided between at least two sub-photodiode regions SPDR.

While each photodiode region PDR has been described as including at least two sub-photodiode regions SPDR in the above-described example embodiments, the example embodiments are not limited thereto. In some example embodiments, each and/or a portion of the photodiode regions PDR may not include sub-photodiode regions (e.g., the sub-photodiode regions may be omitted). When the photodiode regions PDR do not include sub-photodiode regions, each of the pixels PXL of FIG. 2 may be formed on and in each of the photodiode regions PDR. For example, a single Photodiode PD may be formed in each of the photodiode regions PDR.

The first shallow device isolation pattern STI1 may be disposed in a first shallow trench STR1 (see FIG. 7) recessed to a specific depth from the first surface 111 of the first substrate 110.

The first shallow device isolation pattern STI1 may define active regions within the first substrate 110. The first shallow device isolation pattern STI1 may be adjacent to the first surface 111 of the first substrate 110. The first shallow device isolation pattern STI1 may be provided between active regions to electrically isolate the active regions from each other. In some example embodiments, the first shallow device isolation pattern STI1 may define at least one active region within each of the sub-photodiode regions SPDR. In these example embodiments, the first shallow device isolation pattern STI1 may define two active regions within each of the sub-photodiode regions SPDR. When a photodiode region PDR does not include sub-photodiode regions, the first shallow device isolation pattern STI1 may define at least one active region within each of the photodiode regions PDR.

In some example embodiments, the first deep device isolation pattern DTI1 may partially overlap the first shallow device isolation pattern STI1. The overlapping portion between the first deep device isolation pattern DTI1 and the first shallow device isolation pattern STI1 may correspond to a portion of the first shallow device isolation pattern STI1 or a portion of the first deep device isolation pattern DTI1.

The transfer gate TFG may be disposed on the first surface 111 of the first substrate 110. The transfer gate TFG may be disposed above a corresponding active region (hereinafter referred to as a “first active region”) in each of the sub-photodiode regions SPDR. A first gate insulating layer 120 may be disposed between the transfer gate TFG and the first active region. In some example embodiments, a second shallow trench STR2 may be formed in the first shallow device isolation pattern STI1 on opposite sides of a portion of the first active region, exposing opposite side surfaces the portion of the first active region. The transfer gate TFG may be disposed above an upper surface of the portion of the first active region and the exposed opposite surfaces of the portion of the first active region, filling a portion of the second shallow trench STR2. In some example embodiments, the first gate insulating layer 120 may extend to be disposed between the transfer gate TFG and an internal surface of the second shallow trench STR2. For example, the transfer gate TFG may include a pair of vertical portions covering the exposed opposite surfaces of the first active region and a horizontal portion covering the upper surface of the portion of the first active region. As a result, the channel region defined within the first active region below the transfer gate TFG may include the transfer gate TFG a pair of vertical channel portions, respectively adjacent to the exposed opposite side surfaces, and a horizontal channel portion adjacent to the upper surface of the portion of the first active region.

The floating diffusion region FD may be provided in the first active region on one side of the transfer gate TFG. In some example embodiments, the floating diffusion region FD may be a region doped with impurities of a second conductivity type. A ground region GND may be provided in a corresponding active region (hereinafter referred to as a “second active region”) within each of the sub-photodiode regions SPDR. In some example embodiments, the ground region GND may be a region doped with impurities of a first conductivity type. For example, the ground region GND may share the same conductivity type as the first substrate 110. The ground region GND may be configured to receive a ground voltage.

In some example embodiments, a gate spacer 130 may be disposed on side surfaces of the transfer gate TFG. The gate spacer 130 may include an insulating material, different from an insulating material of the first shallow device isolation pattern STI1. For example, when the first shallow device isolation pattern STI1 includes a silicon oxide, the gate spacer 130 may include a silicon nitride and/or a silicon oxynitride. The gate spacer 130 may fill a portion of the second shallow trench STR2. Also, the gate spacer 130 may be disposed on a bottom surface of the second shallow trench STR2.

A lower end of at least a portion of the gate spacer 130 may be disposed at a level between the first and second surfaces 111 and 113 of the first substrate 110. As illustrated in FIG. 6, the at least a portion of the gate spacer 130 may be disposed within the second shallow trench STR2, allowing the lower end of the at least portion of the gate spacer 130 to be lower than the first surface 111 of the first substrate 110.

As illustrated in FIGS. 5 and 6, in the plan view, the second shallow trench STR2 may laterally extend to intersect the first deep device isolation pattern DTI1. A bottom surface of the second shallow trench STR2 may expose the first deep device isolation pattern DTI1.

A capping liner layer 140 may be disposed on the first surface 111 of the first substrate 110 to conformally cover the first surface 111, the first gate insulating layer 120, the gate spacer 130, and the transfer gate TFG. The capping liner layer 140 may fill a portion of the second shallow trench STR2.

The first interlayer dielectric 150 may be provided on the first surface 111 of the first substrate 110 and disposed on the capping liner layer 140. The first interlayer dielectric 150 may cover the first surface 111, the first gate insulating layer 120, the gate spacer 130, the transfer gate TFG, and the capping liner layer 140. The first interlayer dielectric 150 may fill the remaining region of the second shallow trench STR2. In some example embodiments, the capping liner layer 140 may be formed of an insulating material with etch selectivity with respect to the first interlayer dielectric 150. For example, when the first interlayer dielectric 150 is formed of a silicon oxide, the capping liner layer 140 may be formed of a silicon nitride and/or a silicon oxynitride. In some example embodiments, the capping liner layer 140 may be omitted. The first interlayer dielectric 150 may be provided in plurality, and the first interlayer dielectrics 151, 153, and 155 may be sequentially stacked on the first surface 111 of the first substrate 110. The first interlayer dielectric 150 may fill a portion of the second shallow trench STR2.

The first contact complex 160 may include first contact plugs 161 and first contact interconnection 163. The first contact plugs 161 and first contact interconnection 163 may be disposed within the first interlayer dielectrics 151, 153, and 155.

In some example embodiments, the transfer gate TFG may be electrically connected to a corresponding first contact interconnection 163, among the first contact interconnections 163, through a first contact plug 161 provided on the transfer gate TFG.

As illustrated in FIG. 4, the first bonding pad 410 may be disposed within a lowermost layer among the first interlayer dielectrics 151, 153, and 155.

Although not illustrated, a substrate insulating layer may be provided on the second surface 113 of the first substrate 110. The substrate insulating layer may cover the second surface 113 and have a single-layer or multilayer structure. In some example embodiments, the substrate insulating layer may include a silicon-based insulating material (for example, a silicon oxide, a silicon nitride, and/or a silicon oxynitride) and/or an insulating metal oxide.

Color filters CF may be disposed on the substrate insulating layer. In some example embodiments, as illustrated in FIG. 4, the color filters CF may be disposed on the second surface 113 of the first substrate 110 to respectively correspond to pixels. In some example embodiments, each of the color filters CF may vertically overlap a corresponding Photodiode PD. However, the example embodiments are not limited thereto. In some example embodiments, the color filters CF may vertically overlap adjacent Photodiodes PD, respectively.

In some example embodiments, the Photodiodes PD, respectively corresponding to the color filter CF, may be arranged in a matrix. For example, the corresponding Photodiodes PD may form a 2×2 matrix, a 3×3 matrix, or a 4×4 matrix. In some example embodiments, the color filters CF may include a first color filter having a first color, a second color filter having a second color, and a third color filter having a third color. In some example embodiments, the first color may be one of red, green, and blue, the second color may be another one of red, green, and blue, and the third color may be the remaining one of red, green, and blue. Alternatively, the first color may be one of magenta, cyan, and yellow, the second color may be another one of magenta, cyan, and yellow, and the third color may be the remaining one of magenta, cyan, and yellow. However, the example embodiments are not limited thereto. The first to third colors may be various other colors.

In some example embodiments, microlenses ML may be disposed on the second surface 113 of the first substrate 110. For example, the microlenses ML may be disposed on the color filters CF. The microlenses ML may vertically overlap Photodiode PD, respectively. Alternatively, in some example embodiments, each of the microlenses ML illustrated in FIG. 4 may vertically overlap a plurality of adjacent Photodiodes PD. For example, each of the microlenses ML may vertically overlap Photodiodes PD arranged in a 2×2 matrix, a 3×3 matrix, or a 4×4 matrix. In some example embodiments, the number of Photodiodes PD overlapping at least one of the microlenses ML may be different from the number of photodiode(s) PD overlapping at least another one of the microlenses ML. For example, the at least one microlens ML may vertically overlap a pair of adjacent Photodiodes PD, while the at least another micro lens ML may vertically overlap a single Photodiode PD or four or more adjacent Photodiodes PD.

In cross-sectional view, each of the microlenses ML may have an upward convex shape. In some example embodiments, in the plan view, each of the microlenses ML may have a circular shape or an elliptical shape. In at least some example embodiments, the microlenses ML may be formed of a light-transmissive resin.

In some example embodiments, a microlens ML may include a lens pattern and a planarized portion. The planarized portion of the microlens ML may be provided on a color filter CF, and the lens pattern of the microlens ML may be provided on the planarized portion. The lens pattern and the planarized portion may form a single body without a boundary therebetween. The lens pattern may include the same material as the planarized portion. In some example embodiments, the planarized portion may be omitted, and the lens pattern may be directly disposed on the color filter CF.

Referring to FIG. 4, the second structure 200 may include a second substrate 210, a second shallow device isolation pattern STI2, a second gate insulating layer 220, a second interlayer dielectric 250, a second contact complex 260, a second bonding pad 420, and a third bonding pad 430.

The second substrate 210 may have a third surface 211 and a fourth surface 213 opposing the third surface 211. The third surface 211 may be a front surface of the second substrate 210, and the fourth surface 213 may be a rear surface of the second substrate 210. Alternatively, the third surface 211 may be the rear surface, and the fourth surface 213 may be the front surface.

Similarly to the first substrate 110, the second substrate 210 may include impurities of the first conductivity type, thereby having the first conductivity type.

The second shallow device isolation pattern STI2 may be disposed in a shallow trench recessed to a specific depth from the third surface 211 of the second substrate 210.

The second shallow device isolation pattern STI2 may define active regions in the second substrate 210. The second shallow device isolation pattern STI2 may be provided between active regions in the second substrate 210 to electrically isolate the active regions in the second substrate 210 from each other. In some example embodiments, the second shallow device isolation pattern STI2 may be adjacent to the third surface 211.

A reset gate, a select gate, and a source follower gate SFG may be disposed above corresponding active regions in the second substrate 210. In some example embodiments, the rest gate, the select gate, and the source follower gate SFG may be disposed on the third surface 211. The second gate insulating layer 220 may be interposed between the source follower gate SFG and a corresponding active region, between the select gate and a corresponding active region, and between the reset gate and a corresponding active region. Source/drain regions may be formed in the active regions on opposite sides of each gate. For example, the second structure 200 may include the logic transistors RG, SG, and SF described with reference to FIG. 2, 3A, or 3B.

The second interlayer dielectric 250 may include a plurality of second interlayer dielectrics 251, 253, 255, and 257. One or a portion 251, 253, and 255 of the plurality of second interlayer dielectrics 251, 253, 255, and 257 may be disposed on the third surface 211 of the second substrate 210 to cover the third surface 211, the second gate insulating layer 220, the reset gate, the select gate, and the source follower gate SFG. At least another one 257 of the plurality of second interlayer dielectrics 251, 253, 255, and 257 may be disposed on the fourth surface 213 of the second substrate 210 to cover the fourth surface 213.

The second contact complex 260 may include second contact plugs 261 and second contact interconnection 263. The second contact plugs 261 and second contact interconnection 263 may be disposed in the second interlayer dielectrics 251, 253, 255, and 257.

In some example embodiments, the source follower gate SFG may be electrically connected to a corresponding second contact interconnection 263, among the second contact interconnections 263, through the second contact plug 261 formed above the source follower gate SFG.

The second bonding pad 420 may be disposed in an uppermost layer, among the second interlayer dielectrics 251, 253, and 255. The third bonding pad 430 may be disposed in the second interlayer dielectric 257 covering the fourth surface 213.

In some example embodiments, the third structure 300 may include a third substrate 310, a third shallow device isolation pattern STI3, a third gate insulating layer 320, peripheral circuit gates MxG, a third interlayer dielectric 350, a third contact complex 360, and a fourth bonding pad 440.

The third substrate 310 may have a fifth surface 311 and a sixth surface 313 opposing the fifth surface 311. The fifth surface 311 may be a front side of the third substrate 310, and the sixth surface 313 may be a rear surface of the third substrate 310.

Similarly, to the above-described first and second substrates 110 and 210, the third substrate 310 may include impurities of the first conductivity type.

The third shallow device isolation pattern STI3 may be formed in a shallow trench recessed to a specific depth from the fifth surface 311 of the third substrate 310.

The third shallow device isolation pattern STI3 may define active regions in the third substrate 310. The third shallow device isolation pattern STI3 may be provided between active regions to electrically isolate the active regions in the third substrate 310 from each other. In some example embodiments, the third shallow device isolation pattern STI3 may be adjacent to the fifth surface 311 of the third substrate 310.

The peripheral circuit gates MxG may be disposed on corresponding active regions within the third substrate 310. In some example embodiments, the peripheral circuit gates MxG may be disposed on the fifth surface 311 of the third substrate 310. The third gate insulating layer 320 may be disposed between active regions corresponding to the peripheral circuit gates MxG. Peripheral circuit source/drain regions may be disposed in corresponding active regions on opposite sides of each of the peripheral circuit gates MxG.

The third interlayer dielectric 350 may be disposed on the fifth surface 311 of the third substrate 310 to cover the fifth surface 311, the third gate insulating layer 320, and the peripheral circuit gates MxG. The third interlayer dielectric 350 may be provided in plurality, and the third interlayer dielectrics 351, 353, and 355 may be sequentially stacked on the fifth surface 311 of the third substrate 310.

The third contact complex 360 may include third contact plugs 361 and third contact interconnections 363. The third contact plugs 361 and third contact interconnections 363 may be disposed in the third interlayer dielectrics 351, 353, and 355.

In some example embodiments, the peripheral circuit gates MxG may be electrically connected to corresponding third contact interconnections 263, among the third contact interconnections 263, through the third contact plugs 361 provided on the peripheral circuit gates MxG.

The fourth bonding pad 440 may be disposed in an uppermost interlayer dielectric, among the third interlayer dielectrics 351, 353, and 355.

The shallow device isolation patterns STI1, STI2, and STI3 may be formed by a technique in which a shallow trench formed by patterning the first substrate 110 is filled with an insulating material, for example, a shallow trench isolation (STI) technique, and may not penetrate through the substates 110, 210, and 310. The shallow device isolation patterns STI1, STI2, and STI3 may include an insulating material, such as a silicon oxide, a silicon nitride, a silicon oxynitride, or combinations thereof, but the example embodiments are not limited thereto.

The gates TFG, SFG, and MxG may include a conductive material (for example, doped polysilicon, metal, conductive metal nitride, and/or metal silicide). The gate insulating layers 120, 220, and 320 may include an insulating material (for example, a silicon oxide, a silicon nitride, a silicon oxynitride, a high-K dielectrics, or the like). In some example embodiments, additional gate spacers may be provided on opposite side surfaces of the gates SFG and MxG in the second and third structures 200 and 300. The additional gate spacers may include an insulating material (for example, a silicon oxide, a silicon nitride, and/or a silicon oxynitride).

The first to third contact interconnection 163, 263, and 363 may include gate lines TGL, RGL, and SGL (see FIG. 2), power supply voltage lines Vₚᵢₓ, output lines V_{OUT}, ground voltage lines, and local connection lines. The first to third contact plugs 161, 261, and 361 and the first to third contact interconnections 163, 263, and 363 may electrically connect gates and impurity regions (for example, floating diffusion regions FD, source/drain regions, and ground regions GND) to constitute desired circuits (for example, pixel circuits and/or peripheral circuits).

The first to fourth bonding pads 410, 420, 430, and 440 may electrically connect the first to third structures 100, 200, and 300.

In some example embodiments, the first bonding pad 410 and second bonding pad 420 may be bonded to electrically connect the first structure 100 and second structure 200. For example, the floating diffusion region FD of the first structure 100 may be connected to the source follower gate SFG of the second structure 200 through the first contact plugs 161, the first contact interconnection 163, the first bonding pad 410, the second bonding pad 420, the second contact plugs 261, and the second contact interconnection 263.

In some example embodiments, the third bonding pad 430 and fourth bonding pad 440 may be bonded to electrically connect the second structure 200 and third structure 300. For example, the second contact interconnection 263 of the second structure 200 may be connected to the third contact interconnection 363 of the third structure 300 through the second contact plugs 261, the third bonding pad 430, the fourth bonding pad 440, and the third contact plugs 361.

In some example embodiments, the second structure 200 may be bonded in a manner, different from that illustrated in FIG. 4, with vertical inversion, vertical and horizontal inversion, 180-degree rotation, or the like, applied.

For example, the first bonding pad 410 and the third bonding pad 430 may be bonded to electrically connect the first structure 100 and the second structure 200. Accordingly, the floating diffusion region FD of the first structure 100 may be electrically connected to the source follower gate SFG of the second structure 200 through the first contact plugs 161, the first contact interconnections 163, the first bonding pad 410, the third bonding pad 430, the second contact plugs 261, and the second contact interconnections 263.

For example, the second bonding pad 420 and the fourth bonding pad 440 may be bonded to electrically connect the second structure 200 and the third structure 300. Accordingly, the second contact interconnections 263 of the second structure 200 may be electrically connected to the third contact interconnections 363 of the third structure 300 through the second contact plugs 261, the second bonding pad 420, the fourth bonding pad 440, and the third contact plugs 361.

In some example embodiments, the first to fourth bonding pads 410, 420, 430, and 440 may include copper. A combination of the first and second bonding pads 410 and 420, a combination of the first and third bonding pads 410 and 430, a combination of the second and third bonding pads 420 and 430, and a combination of the third and fourth bonding pads 430 and 440 may be bonded using a hybrid bonding technique, such as a copper-to-copper bonding technique. The bonded pads 410 and 420, 410 and 430, 420 and 430, 420 and 440, or 430 and 440 may form a single body without boundaries therebetween.

In some example embodiments, among the first to third interlayer dielectrics 150, 250, and 350, bonded interlayer dielectrics may be covalent to each other. For example, a lowermost first interlayer dielectric 155 may be bonded to an uppermost second interlayer dielectric 255. For example, a lowermost second interlayer dielectric 257 may be bonded to an uppermost third interlayer dielectric 355. When the second structure 200 is inverted (not illustrated; vertically inverted, vertically and horizontally inverted, rotated 180°, or the like) during a bonding process, the lowermost first interlayer dielectric 155 may be bonded to an uppermost second interlayer dielectric 257, and the lowermost second interlayer dielectric 255 may be bonded to an uppermost third interlayer dielectric 355.

Referring to FIG. 8, in some example embodiments, a level of a bottom surface of a second shallow trench STR2 may differ from a level of a bottom surface of a first shallow trench STR1. For example, relative to FIG. 8, the level of the bottom surface of the second shallow trench STR2 may be lower the level of the bottom surface of the first shallow trench STR1. Alternatively, the level of the bottom surface of the second shallow trench STR2 may be higher than the level of the bottom surface of the first shallow trench STR1. However, the example embodiments are not limited thereto. In some example embodiments, the level of the bottom surface of the second shallow trench STR2 may be the same as or substantially similar to the level of the bottom surface of the first shallow trench STR1.

In some example embodiments, the second shallow trench STR2 may be recessed from the first surface 111 of the first substrate 110 to be formed in a portion of the first shallow device isolation pattern STI1, the first deep device isolation pattern DTI1, or the second deep device isolation pattern DTI2.

Referring to FIGS. 5 and 6, in some example embodiments, each of the photodiode regions PDR may include a pair of sub-photodiode regions SPDR, and the second deep device isolation pattern DTI2 may be disposed between the pair of sub-photodiode regions SPDR. The second deep device isolation pattern DTI2 may extend from one side of the first deep device isolation pattern DTI1 and be spaced apart from the opposite side of the first deep device isolation pattern DTI1. For example, the second deep device isolation pattern DTI2 may not be disposed in a portion of a region between the pair of sub-photodiode regions SPDR.

In some example embodiments, the first active region and the floating diffusion region FD may be disposed in each of the pair of sub-photodiode regions SPDR, and the transfer gate TFG and the gate spacer 130 may be disposed on each of the pair of sub-photodiode regions SPDR.

In some example embodiments, the first active regions (or floating diffusion regions FD) disposed in each of the pair of sub-photodiode regions SPDR may be connected to form a single body. The first active regions of the sub-photodiode regions SPDR may be directly connected through a spaced region between the first and second deep device isolation patterns DTI1 and DTI2 to form a single body.

In some example embodiments, in the plan view, the second shallow trench STR2 may laterally extend to cross the first and second deep device isolation patterns DTI1 and DTI2. For example, a portion of the second shallow trench STR2 may be disposed between the first active regions, each defined within a pair of adjacent photodiode regions PDR, across the first deep device isolation pattern DTI1. For example, another portion of the second shallow trench STR2 may be disposed between said first active regions, each defined within a pair of adjacent sub-photodiode regions SPDRs, across the second deep device isolation pattern DTI2.

In the image sensor according to the above-described embodiments, the second shallow trench STR2 may be formed between adjacent transfer gates TFG, and vertical portions of the transfer gates TFG may be disposed within the second shallow trench STR2. Portions of the gate spacers 130, covering the side surfaces of the transfer gates TFG, may also be disposed within the second shallow trench STR2. For example, a substantially planarized bottom surface of the second shallow trench STR2 may be provided between adjacent transfer gates TFG, and the gate spacers 130 and the vertical portions of the transfer gates TFG may be disposed on the substantially planarized bottom surface. Thus, short-circuit between adjacent transfer gates TFG may be protected against (e.g., prevented and/or mitigated). In addition, since electrons have no path to move other than through the channel region under the transfer gates, the electron loss may be reduced (for example, significantly). As a result, the reliability of the image sensor may be improved.

FIG. 9 is a cross-sectional view corresponding to line I-I′ of FIG. 5, illustrating an image sensor according to one or more example embodiments. Hereinafter, the description will be primarily focused on highlighting differences from the above-described embodiments for brevity of description.

Referring to FIG. 9, a portion of the bottom surface of the second shallow trench STR2 may be recessed to define a recess region RR. The transfer gate TFG may extend inwardly of the recess region RR, and the first gate insulation layer 120 may extend to be disposed between the transfer gate TFG and an internal surface of the recess region RR. In some example embodiments, the recess region RR may be provided adjacent to the first active region. Only the transfer gate TFG and the first gate insulation layer 120 filling the recess region RR is illustrated in FIG. 9, but embodiments are not limited thereto. In some example embodiments, the gate spacer 130 and the first interlayer dielectric 150 may also fill a portion of the recess region RR, similarly to the second shallow trench STR2.

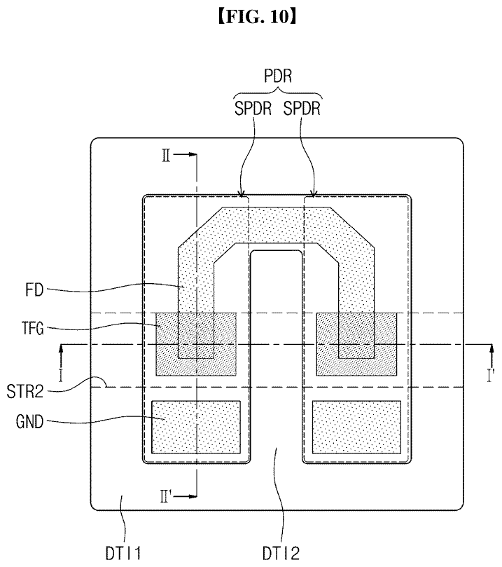

FIG. 10 is a plan view of a portion of an image sensor according to one or more example embodiments. FIG. 11 is a cross-sectional view taken along line II-II′ of FIG. 10.

Referring to FIGS. 10 and 11, the second shallow trench STR2 may expose not only opposite side surfaces of the portion of the first active region but also another side surface of the first active region connected to the opposite side surfaces. For example, the second shallow trench STR2 may expose three side surfaces of the first active region.

The transfer gate TFG may fill a portion of the second shallow trench STR2. In some example embodiments, the transfer gate TFG may be disposed on an upper surface of the portion of the first active region, as well as on the exposed opposite side surfaces and the exposed another side surface of the first active region. The first gate insulating layer 120 may extend to be disposed between the transfer gate TFG and the internal surface of the second shallow trench STR2.

The first interlayer dielectric 150 and the gate spacer 130 may fill a portion of the second shallow trench STR2. In some example embodiments, the first interlayer dielectric 150 and the gate spacer 130 may be provided on the bottom surface of the second shallow trench STR2.

In some example embodiments, a level of the bottom surface of the second shallow trench STR2 may be different from a level of the bottom surface of the first shallow trench STR1. Alternatively, the level of the bottom surface of the second shallow trench STR2 may be the same as (or substantially similar to) the level of the bottom surface of the first shallow trench.

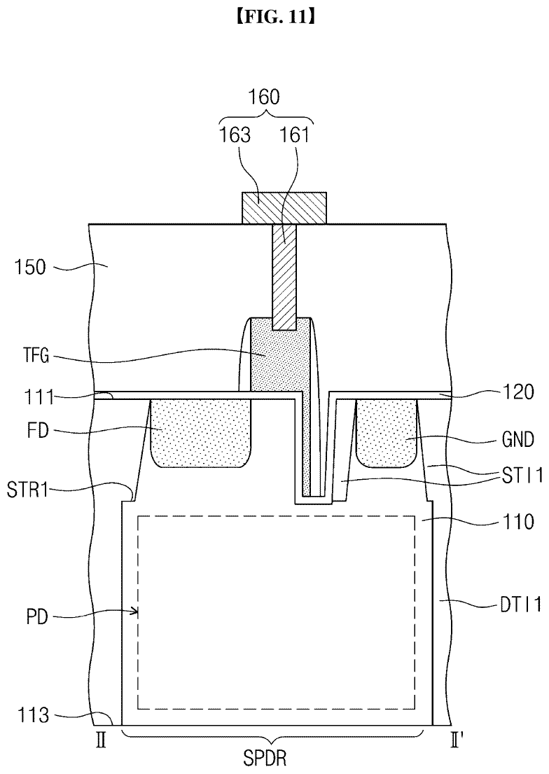

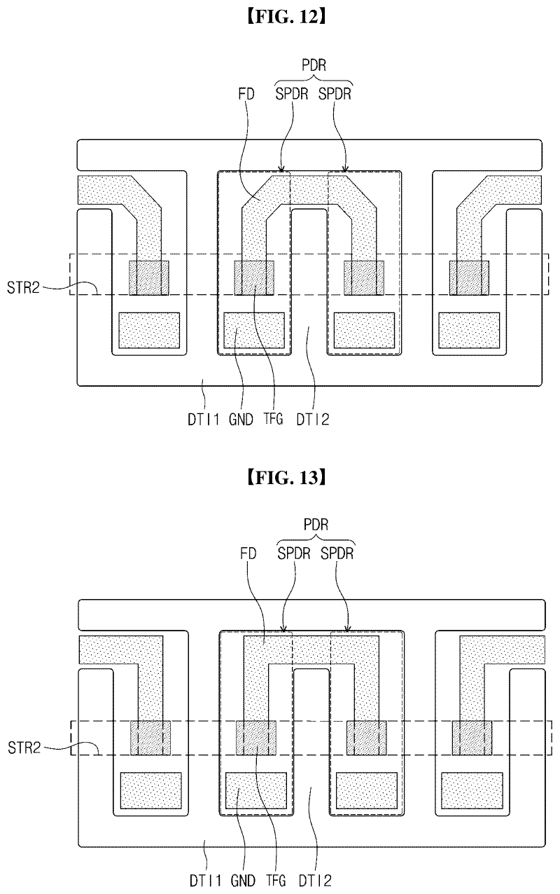

FIGS. 12 to 17 are plan views of portions of image sensors according to one or more example embodiments.

Referring to FIGS. 12 to 17, an image sensor including a pair of sub-photodiode regions SPDR may be modified in various ways. The modifications may include a change in shape of first active regions, a change in shape of transfer gates TFG, or a change in shape of the first active regions and the transfer gates TFG.

Referring to FIG. 12, a second shallow trench STR2 may expose opposite side surfaces of a portion of a floating diffusion region FD, unlike that illustrated in FIGS. 5 and 10. A portion of the second shallow trench STR2, exposing the side surfaces of the floating diffusion region FD, may be filled with a gate spacer 130 and a first interlayer dielectric 150.

Referring to FIGS. 12 to 15, an image sensor according to one or more example embodiments may include first and second deep device isolation patterns DTI1 and DTI2. The second deep device isolation pattern DTI2 may extend from one side of the first deep device isolation pattern DTI1 and be spaced apart from the opposite side of the first deep device isolation pattern DTI1. The first active regions of the pair of sub-photodiode regions SPDR may be directly connected through a region between the sub-photodiode regions SPDR and between the first and second deep device isolation patterns DTI1 and DTI2 to form a single body. Similarly, the floating diffusion regions FD of the pair of sub-photodiode regions SPDR may extend along first active regions connected to each other and be directly connected to form a single body. The floating diffusion regions FD of the sub-photodiode regions SPDR may be connected to each other without boundaries therebetween. Hereinafter, it should be understood that when the first active regions are connected to form a single body, the floating diffusion regions FD are also connected to form a single body.

Referring to FIGS. 12 and 13, the shapes of the first active regions may vary. For example, first active regions connected to form a single body may include a portion extending in an oblique direction, as illustrated in FIG. 12. Alternatively, first active regions connected to form a single body may include a portion extending in a perpendicular direction, as illustrated in FIG. 13.

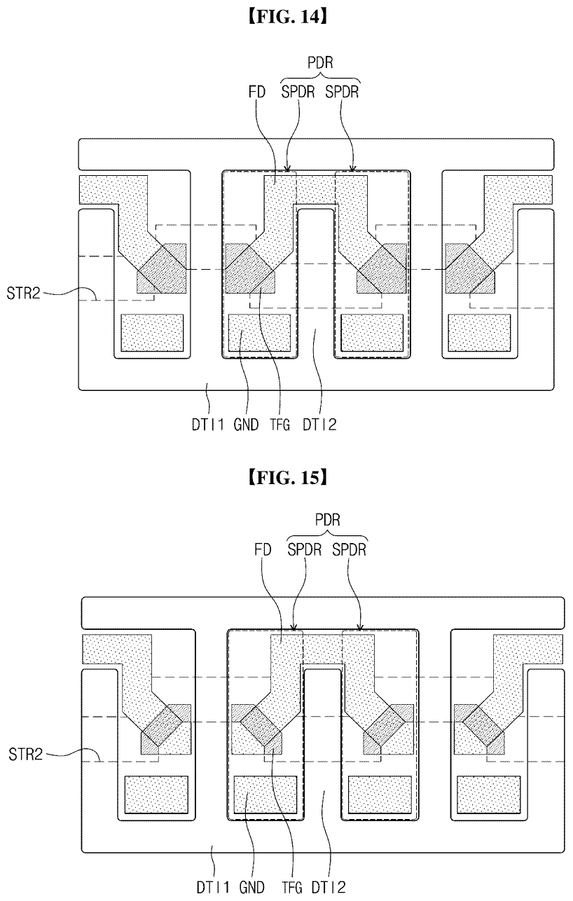

Referring to FIGS. 14 and 15, the shapes of the first active regions and transfer gates TFG may vary. As illustrated in FIG. 14, first active regions connected to form a single body may include both an obliquely extending portion and an orthogonally extending portion, and an end of the first active region and an end of the transfer gate TFG may have pointed shapes. In FIG. 15, the transfer gate TFG may cross the first active region to expose the first active region on opposite sides of the transfer gate TFG.

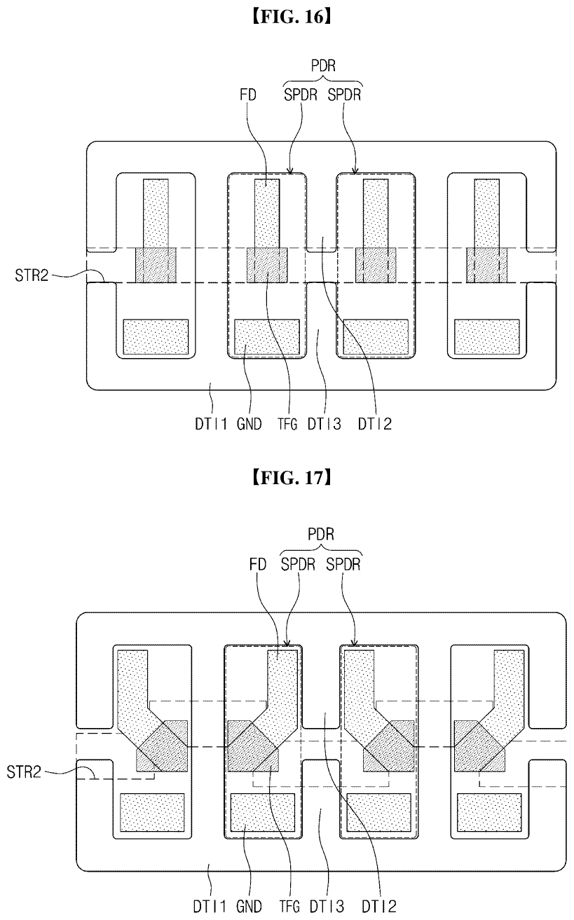

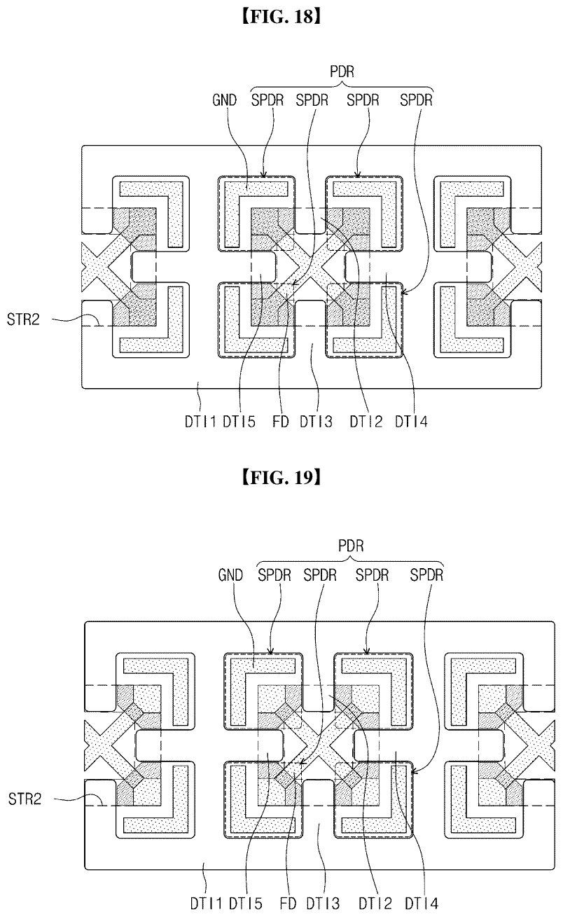

Referring to FIGS. 16 and 17, an image sensor according to one or more example embodiments may include first to third deep device isolation patterns DTI1, DTI2, and DTI3. The second and third deep device isolation patterns DTI2 and DTI3 may extend from one side of the first deep device isolation pattern DTI1 and the opposite side facing that side, respectively, and may be spaced apart from each other. The second and third deep device isolation patterns DTI2 and DTI3 may be disposed between the pair of sub-photodiode regions SPDR. As illustrated in FIG. 16, the first active region may have a bar shape extending in one direction. Alternatively, as illustrated in FIG. 17, the first active region may include a portion extending in the one direction and another portion extending in an oblique direction. In the embodiments of FIGS. 16 and 17, the first active regions of the sub-photodiode regions SPDR may be spaced apart from each other. However, embodiments are not limited thereto. In some example embodiments, the first active regions of the sub-photodiode regions SPDR in FIG. 17 or 18 may be directly connected through a region between the second and third deep device isolation patterns DTI2 and DTI3 to form a single body.

In FIG. 18, an end of the transfer gate TFG and an end of the first active region may have pointed shapes, similarly to that illustrated in FIG. 14.

FIGS. 18 and 19 are plan views of portions of image sensors according to one or more example embodiments.

Referring to FIGS. 18 and 19, each photodiode region PDR may include four sub-photodiode regions SPDR. An image sensor according to one or more example embodiments may include first to fifth deep device isolation patterns DTI1, DTI2, DTI3, DTI4, and DTI5. In some example embodiments, the second and third deep device isolation patterns DTI2, DTI3 may extend from the first and second sides of the first deep device isolation pattern DTI1, respectively, and may be spaced apart from each other. The fourth and fifth deep device isolation patterns DTI4 and DTI5 may extend from the third and fourth sides of the first deep device isolation pattern DTI1, respectively, and may also be spaced apart from each other. The first and second sides may oppose each other, and the third and fourth sides may oppose each other. The first and second sides may be substantially perpendicular to the third and fourth sides. For example, each of the second to fifth deep device isolation patterns DTI2 to DTI5 may be disposed between two adjacent sub-photodiode regions among the four sub-photodiode regions SPDR.

First active regions of the sub-photodiode regions SPDR may be directly connected through regions between the four sub-photodiode regions SPDR and between the second to fifth deep device isolation patterns DTI2 to DTI5 to form a single body. Accordingly, floating diffusion regions FD of the four sub-photodiode regions SPDR may also be directly connected to form a single body. The floating diffusion regions FD of the four sub-photodiode regions SPDR may be connected without boundaries therebetween.

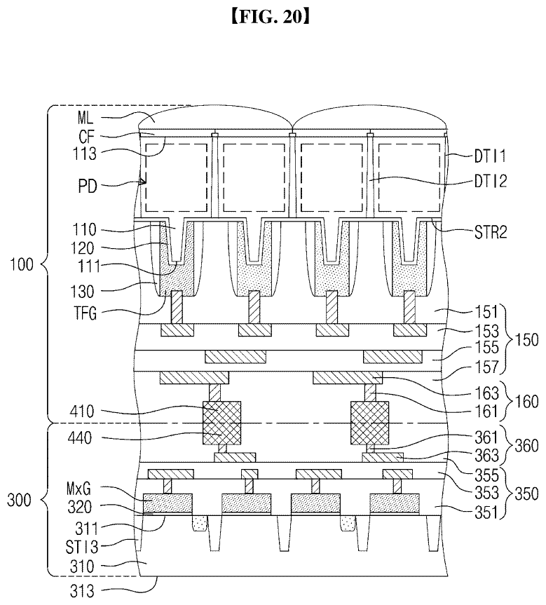

As illustrated in FIGS. 18 and 19, floating diffusion regions FD connected to form a single body may have an X-shape. In some example embodiments, the floating diffusion region FD of FIG. 18 may be disposed in a first active region on one side of a transfer gate TFG. The transfer gate TFG of FIG. 19 may be smaller than that of FIG. 20. The floating diffusion region FD may be formed in a first active region on opposite sides of the transfer gate TFG of FIG. 19.

The above-described second to fifth deep device isolation patterns DTI2 to DTI5 may have the same (or a substantially similar) structure as the first deep device isolation pattern DTI1. For example, the second to fifth deep device isolation patterns DTI2 to DTI5 may also include a conductive isolation layer and an insulating liner. In some example embodiments, the first to fifth deep device isolation patterns DTI1 to DTI5 may be simultaneously formed.

FIG. 20 is a cross-sectional view of an image sensor according to one or more example embodiments.

Referring to FIG. 20, an image sensor according to one or more example embodiments may include a first structure 100 and a third structure 300. The first structure 100 may be stacked on the third structure 300. The first structure 100 may be referred to as a first chip, a photoelectric conversion chip, or a photoelectric conversion structure. The third structure 300 may be referred to as a third chip, a peripheral circuit chip, or a peripheral circuit structure. The first and third structures 100 and 300 may be bonded by one or more bonding methods and electrically connected by one or more connection methods.

First and fourth bonding pads 410 and 440 may electrically connect the first and third structures 100 and 300. In some example embodiments, the first bonding pad 410 and the fourth bonding pad 440 may be bonded to electrically connect the first and third structures 100 and 300. As disclosed above, the first and fourth bonding pads 410 and 440 may include copper and may be bonded using a copper-copper bonding technique. The bonded first and fourth bonding pads 410 and 440 may form a single body without a boundary therebetween.

In some example embodiments, among the first and third interlayer dielectrics 150 and 350, bonded interlayer dielectrics may be covalent to each other. For example, a portion (or a lowermost layer 157) of the first interlayer dielectrics may be bonded to a portion (or an uppermost layer 355) of the third interlayer dielectrics.

The image sensor according to the present embodiment may not include the second structure 200 of FIG. 4. Thus, the first structure 100 of the image sensor may further include logic transistors RG, SG, and SF of FIG. 2, 3A, or 3B. Although not illustrated, a first shallow device isolation pattern may further define active regions for the logic transistors RG, SG, and SF, and reset gates, select gates, and source follower gates may be provided on a first surface of the first substrate 110 along with a transfer gates TFG. The reset gates, the select gates, and the source follower gates may be provided on corresponding active regions.

As described above, in the image sensor of FIG. 20, the first and third structures 100 and 300 may be electrically connected using the first and fourth bonding pads 410 and 440. However, the example embodiments are not limited to thereto. The first and third structures 100 and 300 may be electrically connected via at least one through-silicon via, not illustrated.

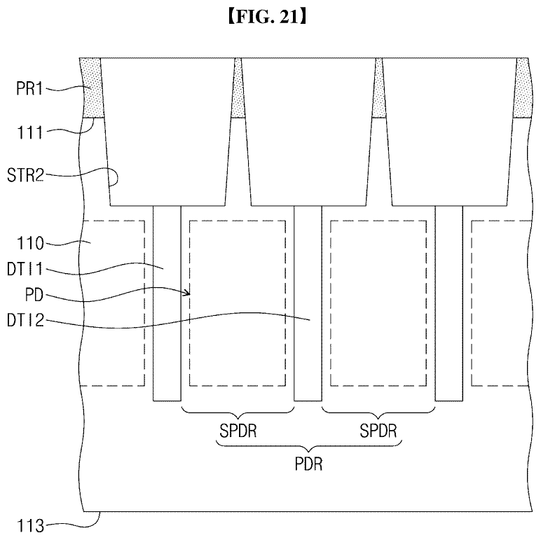

FIGS. 21 to 28 are cross-sectional views illustrating a method of manufacturing a portion of an image sensor according to one or more example embodiments. FIGS. 21 to 28 correspond to cross-sectional views taken along line I-I′ of FIG. 5.

Referring to FIG. 21, a first substrate 110 having first and second surfaces 111 and 113 may be prepared. A patterning process may be performed on the first surface 111 of the first substrate 110 to form a first shallow trench STR1 (see FIGS. 7 and 8), and a first shallow device isolation pattern STI1 (see FIGS. 7 and 8) may be formed within the first shallow trench STR1. First and second deep device isolation patterns DTI1 and DTI2 may be formed in the first substrate 110. The first deep device isolation pattern DTI1 may define a photodiode region PDR, and the second deep device isolation pattern DTI2 may be formed between a pair of sub-photodiode regions SPDR within the photodiode region PDR. In some example embodiments, bottom surfaces of the first and second deep device isolation patterns DTI1 and DTI2 may be spaced apart from the second surface 113 of the first substrate 110. The first shallow device isolation pattern STI1 may define at least one active region within each of the sub-photodiode regions SPDR. For example, the first shallow device isolation pattern STI1 may define first and second active regions within each of the sub-photodiode regions SPDR. Photodiodes PD may be formed within each of the sub-photodiode regions SPDR using an ion implantation process.

In some example embodiments, the first and second deep device isolation patterns DTI1 and DTI2 may be formed after the formation of the first shallow device isolation pattern STI1. Alternatively, the first shallow device isolation pattern STI1 may be formed after the formation of the first and second deep device isolation patterns DTI1 and DTI2. In some example embodiments, the Photodiodes PD may be formed before or after the formation of the first and second deep device isolation patterns DTI1 and DTI2.

A first photoresist pattern PR1 may be formed on the first surface 111 of the first substrate 110 having the deep and shallow device isolation patterns DTI1, DTI2, and STI1. A first photoresist pattern PR1 may include an opening defining a second shallow trench STR2. The opening may expose a portion of the first shallow device isolation pattern STI1. In addition, the opening may also expose portions of the first and second deep device isolation patterns DTI1 and DTI2. The first substrate 110 may be etched using the first photoresist pattern PR1 as an etch mask to form the second shallow trench STR2 in the first shallow device isolation pattern STI1. The second shallow trench STR2 may expose opposite side surfaces of a portion of the first active region. In some example embodiments, portions of the first and second deep device isolation patterns DTI1 and DTI2 may also be etched during the etching process to form the second shallow trench STR2. As a result, the bottom surface of the second shallow trench STR2 may expose the first and second deep device isolation patterns DTI1 and DTI2.

In some example embodiments, the etching process to form the second shallow trench STR2 may be performed until the first substrate 110 is exposed. The exposed surface of the first substrate 110 may include a portion of the bottom surface of the first shallow trench STR1. In some example embodiments, a level of the bottom surface of the second shallow trench STR2 may be the same as (or substantially similar to) a level of the first shallow trench STR1. However, the example embodiments are not limited thereto. In some example embodiments, when the etching process is stopped before the first substrate 110 is exposed or includes overetching, the level of the bottom surface of the second shallow trench STR2 may be different from the level of the first shallow trench STR1.

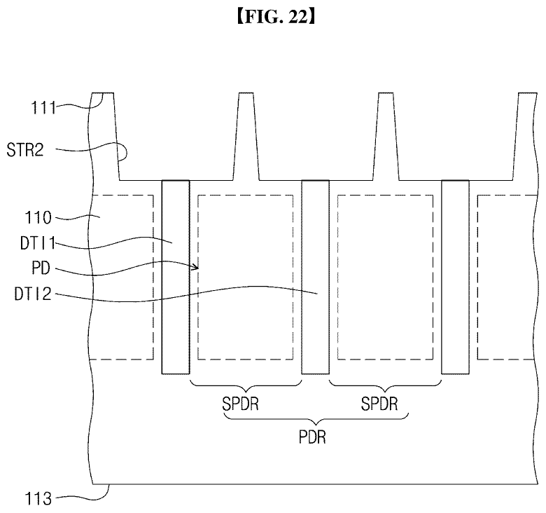

Referring to FIG. 22, the first photoresist pattern PR1 may be removed. The planar shape of the second shallow trench STR2 of FIGS. 21 and 22 may be the same as that illustrated in one of FIGS. 5, 10, and 12 to 19.

In some example embodiments, an additional photoresist pattern may be formed on the first substrate 110 having the second shallow trench STR2. The first substrate 110 may be etched using the additional photoresist pattern as an etch mask to form a recess region RR (see FIG. 9) in the second shallow trench STR2. The recess region RR may be recessed from the bottom surface of the second shallow trench STR2. Then, the additional photoresist pattern may be removed.

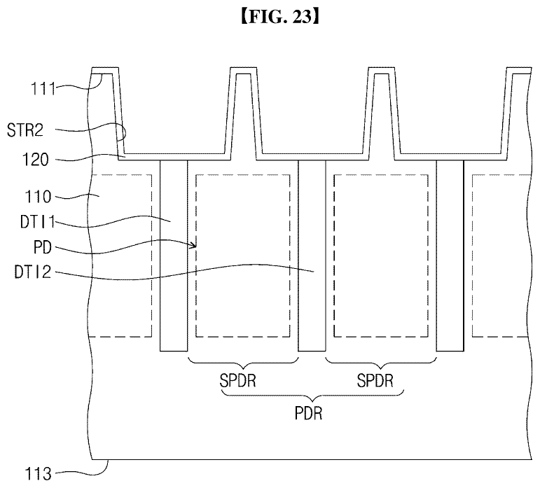

Referring to FIG. 23, a first gate insulating layer 120 may be formed on the first substrate 110. The first gate insulating layer 120 may be conformally formed on the first surface 111 of the first substrate 110 and an internal surface of the second shallow trench STR2. Thus, the first gate insulating layer 120 may be formed on an upper surface of the first active region and the exposed side surfaces of the portion of the first active region. The first gate insulating layer 120 may be formed using at least one of a thermal oxidation process or a deposition process. For example, the first gate insulating layer 120 may include at least one of a silicon oxide, a silicon oxynitride, or a high-K dielectric material.

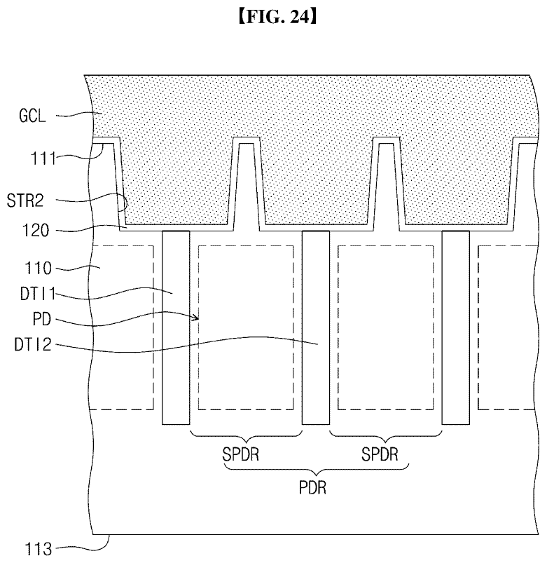

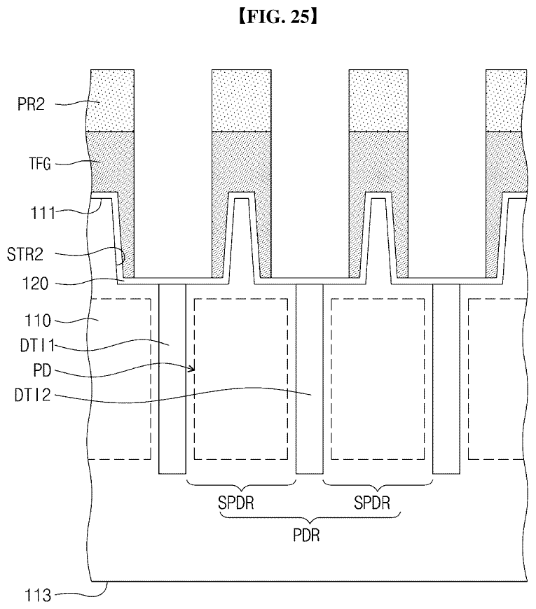

Referring to FIGS. 24 and 25, a gate conductive layer GCL may be formed on the first gate insulating layer 120. The gate conductive layer GCL may fill the second shallow trench STR2. A second photoresist pattern PR2 may be formed on the gate conductive layer GCL. The gate conductive layer GCL may be etched using the second photoresist pattern PR2 as an etch mask to form transfer gates TFG on the first substrate 110. The transfer gates TFG may be formed on the first active regions, respectively. Each of the transfer gates TFG may cover an upper surface and opposite side surfaces of the portion of the first active region.

A floating diffusion region FD (see FIG. 7) may be formed within the first active region on one side of the transfer gate TFG. The floating diffusion region FD may be formed before or after the formation of the transfer gate TFG. A ground region GND (see FIG. 7) may be formed within the second active region.

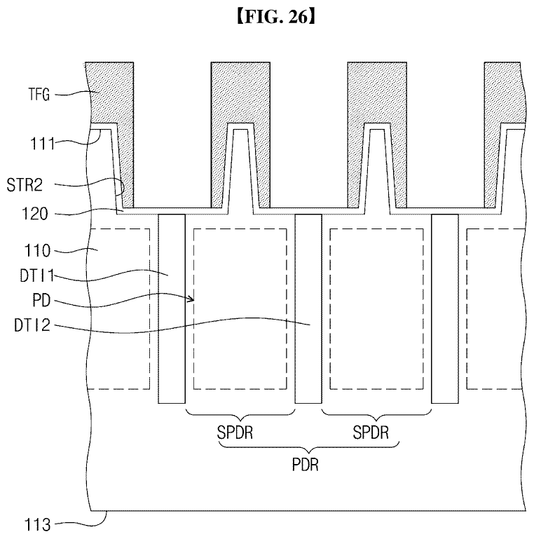

Referring to FIG. 26, the second photoresist pattern PR2 may be removed. The planar shapes of the transfer gates TFG formed in FIGS. 24 to 26 may be the same as (or substantially similar to) the planar shape illustrated in one of FIGS. 5, 10, and 12 to 19.

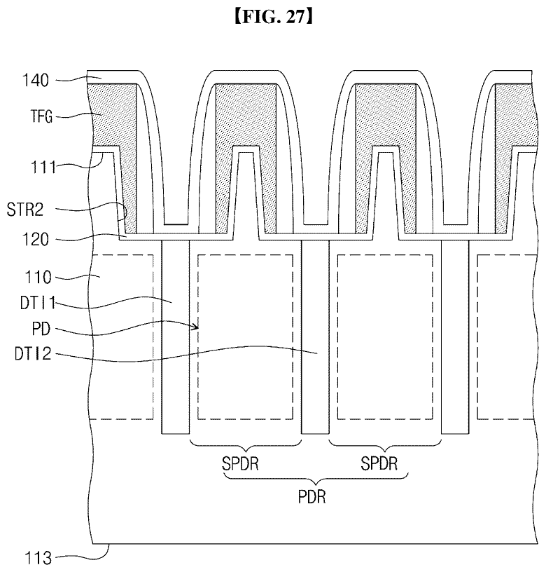

Referring to FIG. 27, gate spacers 130 may be formed on side surfaces of each of the transfer gates TFG. For example, a gate spacer layer may be conformally formed on the first substrate 110 with the transfer gates TFG. The gate spacer layer may be anisotropically etched to form the gate spacers 130. A portion of the gate spacer 130 may be formed within the second shallow trench STR2. Accordingly, a lower end of at least portion of the gate spacer 130 may be disposed at a level between the first and second surfaces 111 and 113 of the first substrate 110. Then, a capping liner layer 140 may be conformally formed on the first substrate 110 with the gate spacer 130. The capping liner layer 140 may cover the gate spacer 130, the transfer gate TFG, and a portion of the bottom surface of the second shallow trench STR2. A portion of the capping liner layer 140 may be formed within the second shallow trench STR2. In some example embodiments, the capping liner layer 140 may be omitted.

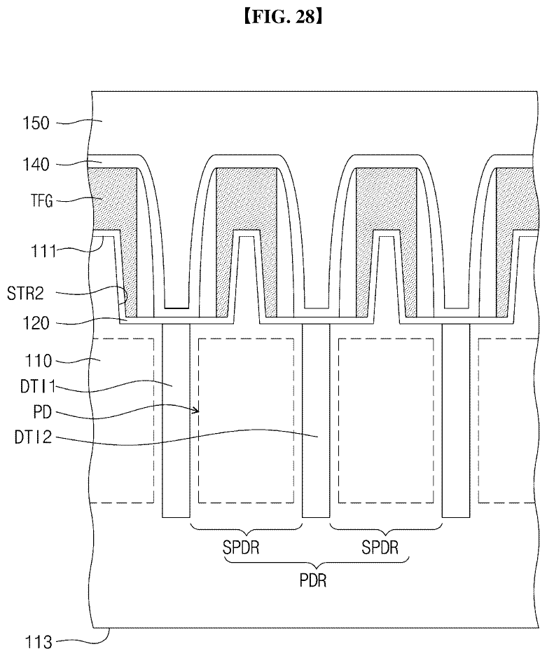

Referring to FIG. 28, a first interlayer dielectric 150 may be formed on the capping liner layer 140. The first interlayer dielectric 150 may fill the remaining region of the second shallow trench STR2. The capping liner layer 140 may be formed of an insulating material having etch selectivity with respect to the first interlayer dielectric 150. For example, the first interlayer dielectric 150 may be formed of a silicon oxide, and the capping liner layer 140 may be formed of a silicon nitride and/or a silicon oxynitride.

Then, other first interlayer dielectrics 153 and 155, a first contact complex 160, and a first bonding pad 410 of FIG. 4 may be formed. In a subsequent process, the second surface 113 of the first substrate 110 may be polished or ground until the first and second deep device isolation patterns DTI1 and DTI2 are exposed.

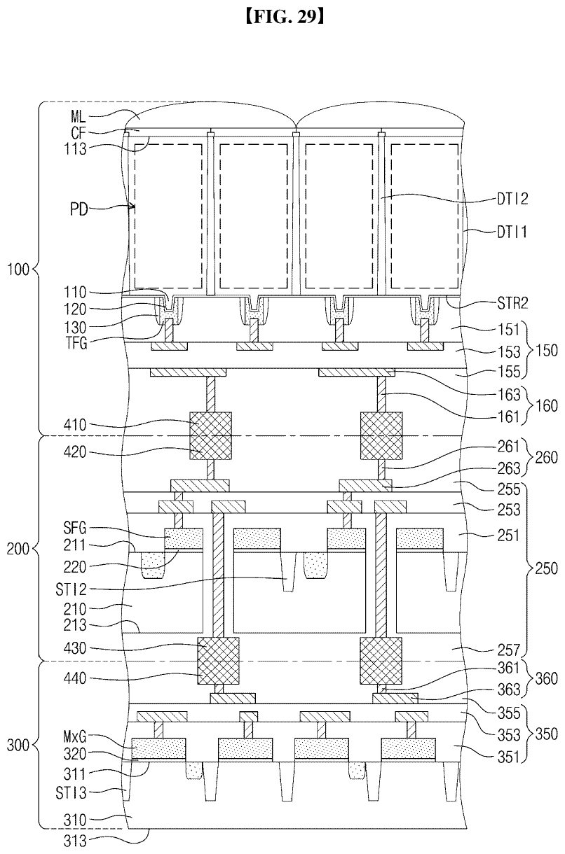

In the above-described embodiments of FIGS. 4 and 20, the transfer gates TFG are illustrated with exaggerated sizes relative to the Photodiodes PD for clarity of description. However, FIG. 29 also illustrates an example to describe the gates TFG, SFG, and MxG of significantly smaller sizes than the Photodiodes PD. A size ratio between the transfer gates TFG and the transistor gates SFG and MxG, and the Photodiodes PD may vary.

As set forth above, according to one or more example embodiments, an electrical short-circuit may be prevented from occurring between transfer gates in an image sensor in advance.

While various embodiments have been illustrated and described above, it will be apparent to those skilled in the art that modifications and variations could be made without departing from the scope of the present inventive concept as defined by the appended claims.

What is claimed is:

1. An image sensor comprising:
a substrate having a first surface and a second surface, the second surface opposing the first surface;
a deep device isolation pattern in the substrate and defining photodiode regions;
a shallow device isolation pattern filling a first shallow trench, the first shallow trench recessed from the first surface of the substrate, the shallow device isolation pattern defining an active region in each of the photodiode regions;
a second shallow trench in the shallow device isolation pattern and on opposite sides of a portion of the active region such that the second shallow trench exposes opposite side surfaces of the portion of the active region;
a transfer gate on an upper surface of the portion of the active region and on the opposite side surfaces exposed by the second shallow trench;
a gate insulating layer between the transfer gate and the active region;
a floating diffusion region in the active region and under one side of the transfer gate; and
a gate spacer on side surfaces of the transfer gate,
wherein a portion of the gate spacer is in the second shallow trench, and a lower end of the portion of the gate spacer in the second shallow trench is between the first surface and the second surface of the substrate.

2. The image sensor of claim 1, further comprising:
an interlayer dielectric on the first surface of the substrate and covering the transfer gate and the gate spacer,
wherein the interlayer dielectric at least partially fills a remaining region of the second shallow trench.

3. The image sensor of claim 1, wherein the second shallow trench extends laterally, in a plan view, to cross the deep device isolation pattern, and
a bottom surface of the second shallow trench exposes the deep device isolation pattern.

4. The image sensor of claim 1,
wherein the transfer gate extends partially into a recess region, the recess region recessed from a portion of a bottom surface of the second shallow trench, and
the gate insulating layer is between the transfer gate and an internal surface of the recess region.

5. The image sensor of claim 1, wherein the second shallow trench further exposes another side surface of the active region connected to the opposite side surfaces of the active region exposed by the second shallow trench.

6. The image sensor of claim 1, wherein
the photodiode regions comprise a pair of sub-photodiode regions;
each of the pair of sub-photodiode regions includes the active region and the floating diffusion region such that each of the photodiode regions includes a plurality of active regions and a plurality of floating diffusion regions; and
the transfer gate and the gate spacer are on each of the pair of sub-photodiode regions such that each of the photodiode regions includes a plurality of transfer gates and a plurality of gate spacers.

7. The image sensor of claim 6, wherein the plurality of active regions of the pair of sub-photodiode regions are connected to form a single body.

8. The image sensor of claim 6, further comprising:
a second deep device isolation pattern extending from the deep device isolation pattern to be between the pair of sub-photodiode regions.

9. The image sensor of claim 6, further comprising:
a second deep device isolation pattern and a third deep device isolation pattern spaced apart from each other, the second deep device isolation pattern and the third deep device isolation pattern extending from the deep device isolation pattern to be between the pair of sub-photodiode regions.

10. The image sensor of claim 1, wherein a portion of the second shallow trench is between the active regions of a pair of the photodiode regions adjacent to each other.

11. The image sensor of claim 1, wherein
each of the photodiode regions comprises four sub-photodiode regions;
each of the sub-photodiode regions includes the active region and the floating diffusion region such that each of the photodiode regions includes a plurality of active regions and a plurality of floating diffusion regions; and
the transfer gate and the gate spacer are on each of the four sub-photodiode regions such that each of the photodiode regions includes a plurality of transfer gates and a plurality of gate spacers.

12. The image sensor of claim 11, wherein
the plurality of active regions of the four sub-photodiode regions are connected to form a single body.

13. The image sensor of claim 11, further comprising:
second to fifth deep device isolation patterns each disposed between two adjacent sub-photodiode regions among the four sub-photodiode regions,
wherein the second to fifth deep device isolation patterns are spaced apart from each other.

14. An image sensor comprising:
a substrate having a first surface and a second surface, the second surface opposite to the first surface;
a deep device isolation pattern in the substrate and defining photodiode regions;
a shallow device isolation pattern filling a first shallow trench, the first shallow trench recessed from the first surface, and the shallow device isolation pattern defining an active region in each of the photodiode regions;
a second shallow trench in the shallow device isolation pattern on opposite sides of a portion of the active region such that the second shallow trench exposes opposite side surfaces of the portion of the active region;
a transfer gate on an upper surface of the portion of the active region and on the opposite side surfaces exposed by the second shallow trench;
a gate insulating layer between the transfer gate and the active region;
a floating diffusion region in the active region on one side of the transfer gate;
a gate spacer on side surfaces of the transfer gate; and
an interlayer dielectric on the first surface of the substrate to cover the transfer gate and the gate spacer,
wherein
the second shallow trench extends laterally, in a plan view, such that the second shallow trench crosses the deep device isolation pattern, and such that a bottom surface of the second shallow trench exposes the deep device isolation pattern,
a portion of the gate spacer is in the second shallow trench, and a lower end of the portion of the gate spacer in the second shallow trench is between the first surface and the second surface of the substrate; and
the interlayer dielectric fills a remaining portion of the second shallow trench.

15. The image sensor of claim 14, wherein the bottom surface of the second shallow trench is at a different level from a bottom surface of the first shallow trench.

16. The image sensor of claim 14, wherein the gate spacer comprises a first insulating material, and
the shallow device isolation pattern comprises a second insulating material different from the first insulating material.

17. The image sensor of claim 14, wherein a portion of the second shallow trench is between the active regions of a pair of the photodiode regions, the pair adjacent to each other.

18. A method of manufacturing an image sensor, the method comprising:
forming a first shallow trench in a substrate such that the first shallow trench defines an active region;
forming a shallow device isolation pattern by filling the first shallow trench;
forming a photoelectric conversion region in the substrate;
forming a second shallow trench by etching a portion of the shallow device isolation pattern, the second shallow trench exposing opposite side surfaces of a portion of the active region;
forming a gate insulating layer after the forming the second shallow trench;
forming a transfer gate on the gate insulating layer such that the transfer gate covers an upper surface of the portion of the active region and the opposite side surfaces exposed by the second shallow trench; and
forming a gate spacer on side surfaces of the transfer gate such that a portion of the gate spacer is formed in the second shallow trench.

19. The method of claim 18, further comprising:
forming a deep device isolation pattern in the substrate such that the deep device isolation pattern defines a photodiode region,
wherein the forming of the second shallow trench comprises etching the portion of the shallow device isolation pattern and a portion of the deep device isolation pattern to form the second shallow trench, and
the active region and the photoelectric conversion region are provided in the photodiode region.

20. The method of claim 18, further comprising:
forming an interlayer dielectric covering the transfer gate and the gate spacer and such that the interlayer dielectric fills a remaining portion of the second shallow trench.
